(19) United States
(12) Patent Application Publication
(10) Pub. No.: US 2026/0190846 A1
(43) Pub. Date: Jul. 2, 2026

(54) METHOD FOR FORMING THIN FILM OF PEROVSKITE COMPOUND AND METHOD FOR MANUFACTURING SOLAR CELL USING SAME

(71) Applicant: JUSUNG ENGINEERING CO., LTD., Gwangju-si, Gyeonggi-do (KR)

(72) Inventors: Jae Ho KIM, Yongin-si, Gyeonggi-do (KR); Chul Joo HWANG, Yongin-si, Gyeonggi-do (KR)

(21) Appl. No.: 18/868,514

(22) PCT Filed: Jun. 1, 2023
(86) PCT No.: PCT/KR2023/007519

§ 371 Date: Nov. 22, 2024

(30) Foreign Application Priority Data
Jun. 7, 2022 (KR) 10-2022-0068741

(51) Int. Cl. H10K 71/00; C23C 16/30; C23C 16/455; H10K 30/10; H10K 30/50

(52) U.S. Cl. CPC H10K 71/311; C23C 16/30; C23C 16/45553; H10K 30/10; H10K 30/50

(57) ABSTRACT

The present inventive concept provides a method for forming a thin film of a perovskite compound, the method comprising: a step for depositing a perovskite compound by reacting at least one compound selected from amine-based compounds and amidine-based compounds, an organometallic compound including a divalent cation, and at least one halogenated hydrogen; and a step for removing impurities present in the perovskite compound.

### TECHNICAL FIELD

The present inventive concept relates to method of forming a thin film of a perovskite compound and method of manufacturing a solar cell using the same.

### BACKGROUND ART

In the related art, a solution process is mainly used in manufacturing solar cells using perovskite compounds. The solution process is to apply a solution of a perovskite compound on a substrate by spin coating, spray coating, or slot die after preparing the solution by dissolving a perovskite compound in a predetermined solvent.

This solution process is not problematic when applying the solution of a perovskite compound to a substrate with a flat surface, but when the solution of a perovskite compound is applied to a crystalline silicon substrate with a pyramid structure for forming a tandem solar cell, it is difficult to form a thin film with a uniform thickness.

In order to solve this problem, a method of forming a film of a perovskite compound through a deposition process has been devised. However, the film of the perovskite compound formed by the deposition process has a problem that the crystal structure changes easily when exposed to an atmosphere, reducing the efficiency of the solar cell.

### DISCLOSURE

### Technical Problem

The present inventive concept is devised to solve the above-described problem and is for providing method of forming a thin film of a perovskite compound and method of manufacturing a solar cell using the same, capable of preventing a change in a crystal structure while using a deposition process.

### Technical Solution

To accomplish the above-described objects, an embodiment of the present inventive concept provides a method of forming a thin film of a perovskite compound comprising a process of depositing a perovskite compound by reacting at least one compound selected from amine-based compounds and amidine-based compounds, organic metal compounds containing a divalent positive ion, and at least one hydrogen halide; and a process of removing impurities in the deposited perovskite compound.

Another embodiment of the present inventive concept provides a method of manufacturing a solar cell comprising a process of forming a crystalline solar cell; a process of forming a buffer layer on the crystalline solar cell; a process of forming a perovskite solar cell on the buffer layer; and a process of forming a first electrode on the perovskite solar cell and a second electrode on the crystalline solar cell, wherein the process of forming a perovskite solar cell comprises a process of forming a thin film of a perovskite compound, and wherein the process of forming a thin film of a perovskite compound comprises a process of depositing a perovskite compound by reacting at least one compound selected from amine-based compounds and amidine-based compounds, organic metal compounds containing a divalent positive ion, and at least one hydrogen halide; and a process of removing impurities in the deposited perovskite compound.

### Advantageous Effect

According to the present inventive concept, the following effects may be realized.

According to an embodiment of the present inventive concept, when a perovskite compound is formed by a deposition process such as CVD or ALD, impurities present in a dangling bond state in the perovskite compound are removed after the deposition process or at the same time. Therefore, changes in the crystal structure of the perovskite compound may be prevented, and thus the efficiency of the solar cell may be improved.

### DESCRIPTION OF DRAWINGS

FIG. 1 is a process diagram for forming a thin film of a perovskite compound according to an embodiment of the present inventive concept.

FIG. 2 is a crystal structure of a perovskite compound after a deposition process according to an embodiment of the present inventive concept.

FIG. 3 is a crystal structure of a perovskite compound after a deposition process and an impurity removal process according to an embodiment of the present inventive concept.

FIG. 4 is a process diagram for forming a thin film of a perovskite compound according to another embodiment of the present inventive concept.

FIG. 5A is a thin film sample of a perovskite compound immediately after the deposition process according to an embodiment of this inventive concept.

FIG. 5B is a thin film sample of a perovskite compound exposed to the atmosphere after the deposition process according to an embodiment of this inventive concept.

FIG. 5C is a thin film sample after adding a cleaning material to a thin film sample of a perovskite compound exposed to the atmosphere after the deposition process in accordance with an embodiment of this inventive concept.

FIG. 6A is an XRD analysis result of a thin film sample of a perovskite compound exposed to the atmosphere after a deposition process according to an embodiment of this inventive concept.

FIG. 6B is an XRD analysis result of a thin film sample after adding a cleaning material to a thin film sample of a perovskite compound exposed to the atmosphere after a deposition process according to an embodiment of this inventive concept.

FIGS. 7A to 7E are process cross-sectional views illustrating a method of manufacturing a solar cell according to an embodiment of the present inventive concept.

### MODE FOR INVENTIVE CONCEPT

Advantages and features of the present inventive concept, and implementation methods thereof will be clarified through following embodiments described with reference to the accompanying drawings. The present inventive concept may, however, be embodied in different forms and should not be construed as limited to the embodiments set forth herein. Rather, these embodiments are provided so that this inventive concept will be thorough and complete, and will fully convey the scope of the present inventive concept to those skilled in the art. Furthermore, the present inventive concept is only defined by scopes of claims.

A shape, a size, a ratio, an angle, and a number disclosed in the drawings for describing embodiments of the present inventive concept are merely an example, and thus, the present inventive concept is not limited to the illustrated details. Like reference numerals refer to like elements throughout. In the following description, when the detailed description of the relevant known technology is determined to unnecessarily obscure the important point of the present inventive concept, the detailed description will be omitted. In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a time relationship, for example, when the temporal order is described as ‘after˜’, ‘subsequent˜’, ‘next˜’, and ‘before˜’, a case which is not continuous may be included unless ‘just’ or ‘direct’ is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present inventive concept.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present inventive concept may be partially or overall coupled to or combined with each other, and may be variously inter-operated with each other and driven technically as those skilled in the art can sufficiently understand. The embodiments of the present inventive concept may be carried out independently from each other, or may be carried out together in co-dependent relationship.

Hereinafter, preferable embodiments of the present inventive concept will be described in detail with reference to the accompanying drawings.

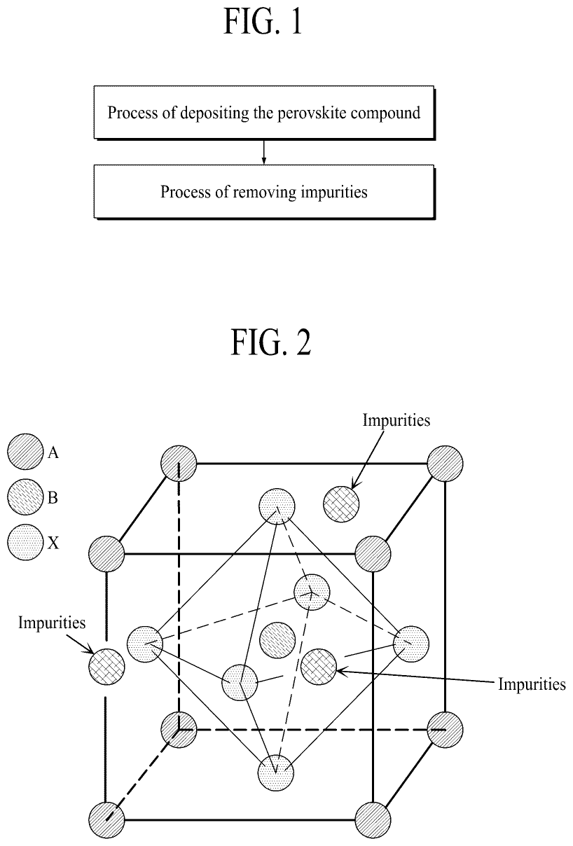

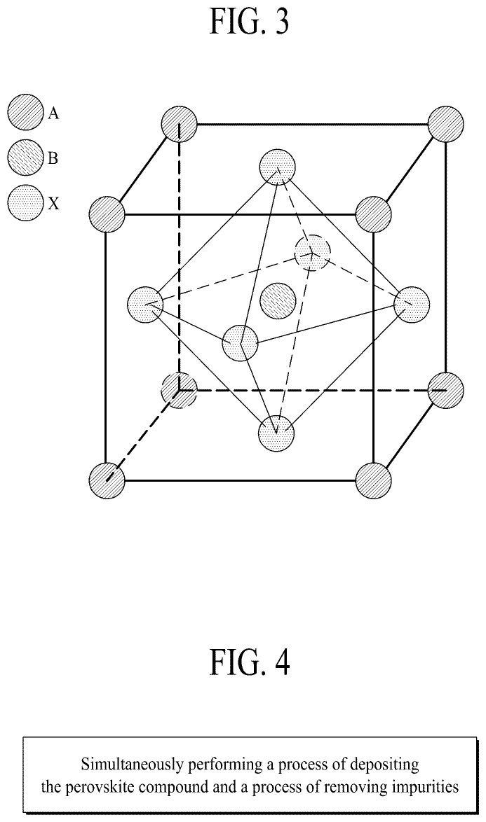

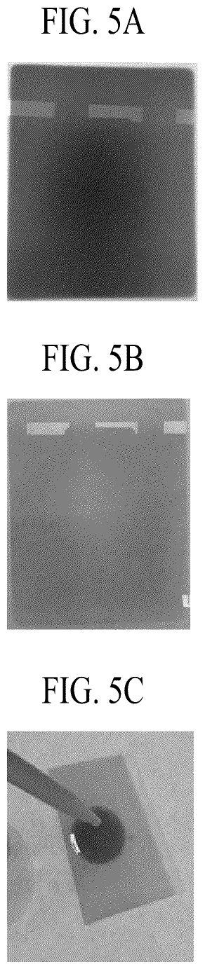

FIG. 1 is a process diagram for forming a thin film of a perovskite compound according to an embodiment of the present inventive concept, FIG. 2 is a crystal structure of a perovskite compound after a deposition process according to an embodiment of the present inventive concept, and FIG. 3 is a crystal structure of a perovskite compound after a deposition process and an impurity removal process according to an embodiment of the present inventive concept.

As shown in FIG. 1, the thin film of the perovskite compound according to an embodiment of the present inventive concept may be formed through a process of depositing the perovskite compound and a process of removing impurities in the deposited perovskite compound.

According to an embodiment of this inventive concept, the perovskite compound deposition process includes depositing ABX₃ compounds by reacting at least one compound selected from amine-based compounds and amidine-based compounds, organic metal compounds containing a divalent positive ion, and at least one hydrogen halide through chemical vapor deposition (CVD) or Atomic Layer Deposition (ALD).

In the ABX₃, the A may consist of the monovalent organic positive ion of the amine-based compound, the monovalent organic positive ion of the amidine-based compound, or the monovalent organic positive ion of the amine-based compound and the monovalent organic positive ion of the amidine-based compound. The A may have a structure where the monovalent organic positive ion of the amine-based compound is included therein at an x ratio and the monovalent organic positive ion of the amidine-based compound is included therein at a y ratio. In this case, each of x and y is greater than 0, and x+y=1.

In the ABX₃, the B consists of the divalent positive ion of the organic metal compound.

In the ABX₃, the X consists of one or more halogen elements.

The amine-based compound may be selected from the group consisting of methylamine, ethylamine, and phenethylamine.

The amidine-based compound may consist of formamidine.

The organic metal compound including the divalent positive ion may include metal selected from the group consisting of lead (Pb), tin (Sn), germanium (Ge), antimony (Sb), bismuth (Bi), and barium (Ba).

In detail, the organic metal compound including the divalent positive ion may include a compound represented by the following Formula 1:

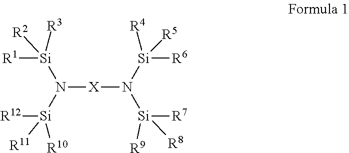

(In the Formula 1, each of R¹ to R¹² consists of hydrogen or an alkyl group independently, and X is selected from the group consisting of Pb, Sn, Ge, Sb, Bi, and Ba)

Alternatively, the organic metal compound including the divalent positive ion may be selected from among the group consisting of Pb(CH₃)₄, Pb(C₂H₅)₄, Pb(SCN)₂, (C₂H₅)₃PbOCH₂C(CH₃)₃, Pb(C₁₁H₁₉O₂)₂, Pb((CH₃)₃C—COCHCO—C(CH₃)₃)₂, Pb((C₆H₅)₂PCH₂P(C₆H₅)₂)₂, Pb(N(CH₃)₂C(CH₃)₂OH)₂, and C₁₂H₂₈ N₂O₂Pb.

A light absorption rate, an optical band gap, carrier mobility, and material stability of a finally obtained perovskite compound may be adjusted based on the kind of the organic metal compound including the divalent positive ion.

The hydrogen halide may be selected from the group consisting of HI, HBr, HF, and HCl. The optical band gap of the finally obtained perovskite compound may be adjusted based on the kind of the hydrogen halide.

The amine-based compound, the amidine-based compound, the organic metal compound including the divalent positive ion, and the hydrogen halide include a material which is vaporized at a temperature within a range of a room temperature to 200° C., and preferably, include a material which is vaporized at a temperature within a range of 50° C. to 150° C. Therefore, in a process of manufacturing a compound of the ABX₃, a chemical vapor deposition (CVD) process or an atomic layer deposition (ALD) process may be performed at a temperature of 200° C. or less (preferably, a temperature of 150° C. or less), and thus, an organic material of a finally obtained compound of ABX₃ may be prevented from being decomposed in performing the CVD process or the ALD process. Also, plasma may be applied in performing the CVD process or the ALD process.

According to another embodiment of this inventive concept, the perovskite compound deposition process includes depositing CABX₃ compounds by reacting at least one compound selected from amine-based compounds and amidine-based compounds, at least one alkali metal-based compound, organic metal compounds containing a divalent positive ion, and at least one hydrogen halide through chemical vapor deposition (CVD) or Atomic Layer Deposition (ALD).

In the CABX₃, the A may consist of the monovalent organic positive ion of the amine-based compound, the monovalent organic positive ion of the amidine-based compound, or the monovalent organic positive ion of the amine-based compound and the monovalent organic positive ion of the amidine-based compound.

In the CABX₃, the C may consist of the at least one alkali metal-based compound.

The CA may have a structure where the monovalent organic positive ion of the amine-based compound is included therein at an x ratio, the monovalent organic positive ion of the amidine-based compound is included therein at a y ratio, and a monovalent position ion of an alkali metal is included therein at a z ratio. In this case, each of x, y, and z is greater than 0, and x+y+z=1.

In the CABX₃, the B consists of the divalent positive ion, and the X consists of one or more halogen elements.

The amine-based compound, the amidine-based compound, the organic metal compound including the divalent positive ion, and the hydrogen halide are as described above, and thus, their repeated descriptions are omitted.

The alkali metal-based compound may include a compound represented by the following Formula 2:

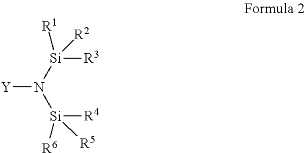

(In the Formula 2, each of R¹ to R⁶ consists of hydrogen or an alkyl group independently, and the Y is an alkali metal)

As described above, according to another embodiment of the present inventive concept, at least one alkali metal-based compound may be added to a reactant, and thus, the instability of a monovalent organic positive ion vulnerable to water, heat, and plasma may be complemented.

According to one embodiment, the process of depositing ABX₃ compounds through the CVD process may include simultaneously supplying at least one compound selected from the amine-based compound and the amidine-based compound, the organic metal compounds containing a divalent positive ion, and the at least one hydrogen halide into a process chamber.

According to one embodiment, the process of depositing ABX₃ compounds through the ALD process may include a process of supplying at least one compound selected from the amine-based compound and the amidine-based compound, and the organic metal compounds containing a divalent positive ion as a source material into a process chamber, a process of purging the source material, a process of supply at least one hydrogen halide as a reaction material into the process chamber, and a process of purging the reaction material. The process of supplying the at least one hydrogen halide as the reaction material may be performed in a plasma state, and is the same in the following embodiments.

According to another embodiment, the process of depositing ABX₃ compounds through the ALD process may include a process of supplying at least one compound selected from the amine-based compound and the amidine-based compound as a first source material into a process chamber, a process of purging the first source material, a process of supplying at least one hydrogen halide as a first reaction material into the process chamber, a process of purging the first reaction material, a process of supplying the organic metal compounds containing a divalent positive ion as a second source material into the process chamber, a process of purging the second source material, a process of supplying at least one hydrogen halide as a second reaction material into the process chamber, and a process of purging the second reaction material.

According to another embodiment, the process of depositing ABX₃ compounds through the ALD process may include a process of supplying at least one compound selected from the amine-based compound and the amidine-based compound as a first source material into a process chamber, a process of purging the first source material, a process of supplying at least one hydrogen halide as a first reaction material into the process chamber, a process of purging the first reaction material, a process of supplying the organic metal compounds containing a divalent positive ion as a second source material and supplying at least one hydrogen halide as a second reaction material into the process chamber, and a process of purging the second source material and the second reaction material. In this case, the first source material and the second source material may be switched with each other.

According to another embodiment, the process of depositing ABX₃ compounds through the ALD process may include a process of supplying at least one compound selected from the amine-based compound and the amidine-based compound as a first source material into a process chamber, a process of purging the first source material, a process of supplying at least one hydrogen halide as a first reaction material and the organic metal compounds containing a divalent positive ion as a second source material into the process chamber, and a process of purging the first reaction material and the second source material. In this case, the first source material and the second source material may be switched with each other.

Referring to FIG. 2, the perovskite compound formed through a deposition process such as CVD or ALD may have a structure in which the ABX₃ compound contains impurities.

In the crystal structure of the perovskite compound including the ABX₃ compound, the A compound can consist of a hexahedral structure, for example a cubic structure. That is, the A compound is placed at the apex of the hexahedral structure, and a hexahedral structure is formed with upper and lower surfaces in parallel to each other, and four sides in contact with each of the upper and lower surfaces.

In the crystal structure of the perovskite compound including the ABX₃ compound, the X compound may have an octahedral structure provided in the hexahedral structure, for example, a regular octahedral structure. That is, the X compound is disposed at the apex of the octahedral structure. At this time, the upper apex of the octahedral structure is in contact with the upper surface of the hexahedral structure made of A compound, the lower apex of the octahedral structure is in contact with the lower surface of the hexahedral structure made of A compound, and four apexes of the central rectangular structure of the octahedral structure are in contact with four sides of the hexahedral structure.

In the crystal structure of the perovskite compound including the ABX₃ compound, the B compound is disposed in the center of the hexahedral structure or in the center of the octahedral structure. Accordingly, the B compound may be disposed in the center of the central rectangular structure of the octahedral structure.

Eight hexahedrons are in contact with each other at one apex made of the A compound, two hexahedrons are in contact with each other at one apex made of the X compound, and the B compound is provided in one hexahedron. Therefore, the ABX₃ compound may be composed of 1 mole of A compound, 1 mole of B compound, and 3 moles of X compound.

The impurities may be included in the crystal structure of the perovskite compound including the ABX₃ compound. The impurities may be chemically bonded to the ABX₃ compound, but may be included in a dangling bond state. The impurities may be present on the surface of the hexahedron or may be present inside the hexahedron.

The impurity may include the A compound, for example, methylamine, ethylamine, phenethylamine, or formamidine. A compound that is not chemically bonded to the X compound and the B compound may be included in a crystal structure of a perovskite compound including the ABX₃ compound in a dangling bond state.

In addition, the impurities may be made of hydrogen halide (HX) such as HI, HBr, HF, or HCl. The hydrogen halide (HX) that is not chemically bonded to the A compound and the B compound may be included in a crystal structure of the perovskite compound including the ABX₃ compound in a dangling bond state.

When a perovskite compound is formed by a deposition process such as CVD or ALD, impurities in a dangling bond state exist in the perovskite compound, and such impurities can easily change the crystal structure of the perovskite compound. Therefore, this inventive concept prevents changes in the crystal structure of the perovskite compound by removing impurities present in the perovskite compound, thereby improving the efficiency of the solar cell. The process of removing the impurities will be described below.

Referring back to FIG. 1, the process of removing impurities from the deposited perovskite compound includes adding a cleaning material to the deposited perovskite compound to chemically bond the impurities and the cleaning material.

In the process of adding the cleaning material, the cleaning material may be supplied in a liquid state or in a gaseous state.

The process of supplying the cleaning material in a liquid state may be performed using a solution device such as spin coating, spray coating, slot-die, nozzle printing, or ink-jet.

The process of supplying the cleaning material in a gaseous state may be performed using a CVD or ALD chamber, in which a vaporizer or a bubbler system for vaporizing the cleaning material may be connected to the CVD or ALD chamber.

The cleaning material includes an organic material capable of reacting with at least one of an amine-based compound, an amidine-based compound, and hydrogen halide. In particular, the cleaning material may be made of an organic material including carbon (C), hydrogen (H), and oxygen (O), for example, C₃H₈O.

When the C₃H₈O as the cleaning material are supplied in case that the impurity is formed of, for example, methyl amine, the methyl amine and the C₃H₈O are combined to generate CH₃NHOH (methylhydroxylamine) and C₃H₈ (propane) as shown in Reaction Formula 1 below.

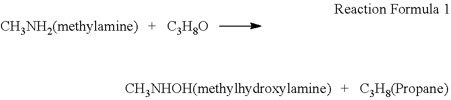

The CH₃NHOH (methylhydroxylamine) generated in Reaction Formula 1 may be vaporized and removed by a subsequent heat treatment process. As a result, impurities composed of methyl amine can be removed in the form of CH₃NHOH (methylhydroxylamine) by reacting with C₃H₈O of a cleaning material.

When the C₃H₈O as the cleaning material are supplied in case that the impurity is formed of, for example, hydrogen iodide (HI), the hydrogen iodide (HI) and the C₃H₈O are combined to generate C₂H₅I (ethyliodine) and CH₃OH (methanol) as shown in Reaction Formula 2 below.

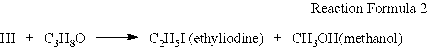

The C₂H₅I (ethyliodine) generated in Reaction Formula 2 may be vaporized and removed by a subsequent heat treatment process. As a result, impurities composed of hydrogen iodide (HI) can be removed in the form of C₂H₅I (ethyliodine) by reacting with C₃H₈O of a cleaning material.

Referring to FIG. 3, when the impurities are removed by adding the cleaning material to the perovskite compound formed through a deposition process, a crystal structure of the ABX₃ compound may be obtained.

The crystal structure of FIG. 3 is the same as the crystal structure of FIG. 2 except that impurities are removed from the crystal structure of FIG. 2, and thus a repeated description of the crystal structure of the ABX₃ compound will be omitted.

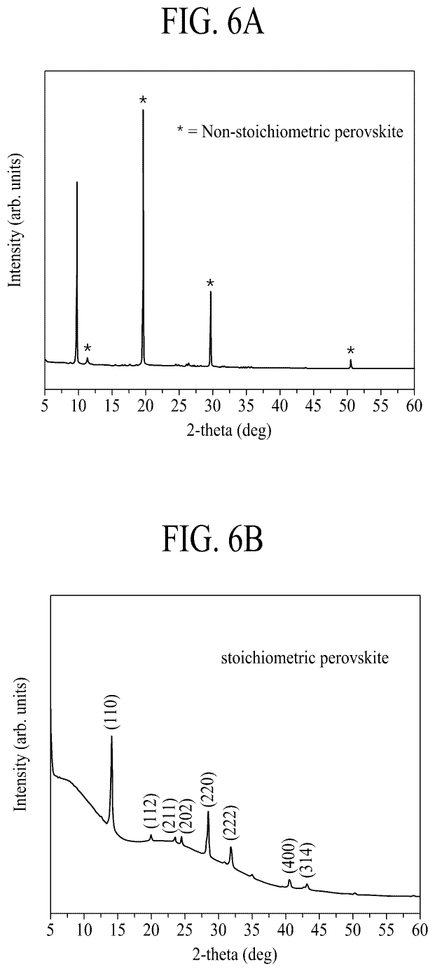

FIG. 4 is a process diagram for forming a thin film of a perovskite compound according to another embodiment of the present inventive concept.

As shown in FIG. 4, the thin film of the perovskite compound according to another embodiment of the present inventive concept may be formed by simultaneously performing a process of depositing the perovskite compound and a process of removing impurities in the deposited perovskite compound.

According to one embodiment, the process of removing impurities while depositing the compound of ABX₃ with a CVD process may include a process of simultaneously supplying at least one compound selected from the amine-based compound and the amidine-based compound, the organic metal compounds containing a divalent positive ion, the at least one hydrogen halide, and an organic material constituting the cleaning material into a process chamber. In this case, a vaporizer or a bubbler system for vaporizing the organic material may be connected to the CVD chamber. In the case of the ALD process described below, a vaporizer or bubbler system for vaporizing the organic material may be connected to the ALD chamber.

According to another embodiment, the process of removing impurities while depositing the compound of ABX₃ with the ALD process may include a process of supplying at least one compound selected from the amine-based compound and the amidine-based compound, and the organic metal compounds containing a divalent positive ion as a source material into a process chamber, a process of purging the source material, a process of supplying at least one hydrogen halide as a reaction material and the organic material constituting the cleaning material into the process chamber, and a process of purging the reaction material.

According to another embodiment, the process of removing impurities while depositing the compound of ABX₃ with the ALD process may include a process of supplying at least one compound selected from the amine-based compound and the amidine-based compound, and the organic metal compounds containing a divalent positive ion as a source material into a process chamber, a process of purging the source material, a process of supply at least one hydrogen halide as a first reaction material into the process chamber, a process of purging the first reaction material, a process of supply the organic material constituting the cleaning material as a second reaction material into the process chamber, and a process of purging the second reaction material. In this case, the first reaction material and the second reaction material may be switched with each other.

According to another embodiment, the process of removing impurities while depositing the compound of ABX₃ with the ALD process may include a process of supplying at least one compound selected from the amine-based compound and the amidine-based compound as a first source material into a process chamber, a process of purging the first source material, a process of supplying at least one hydrogen halide as a first reaction material into the process chamber, a process of purging the first reaction material, a process of supplying the organic metal compounds containing a divalent positive ion as a second source material into the process chamber, a process of purging the second source material, a process of supplying at least one hydrogen halide as a second reaction material into the process chamber, a process of purging the second reaction material, a process of supply the organic material constituting the cleaning material as a third reaction material into the process chamber, and a process of purging the third reaction material. In this case, the first source material and the second source material may be switched with each other, the first to third reaction materials may be switched with one another, and these are the same in the following embodiments.

According to another embodiment, the process of removing impurities while depositing the compound of ABX₃ with the ALD process may include a process of supplying at least one compound selected from the amine-based compound and the amidine-based compound as a first source material into a process chamber, a process of purging the first source material, a process of supplying at least one hydrogen halide as a first reaction material into the process chamber, a process of purging the first reaction material, a process of supplying the organic metal compounds containing a divalent positive ion as a second source material into the process chamber, a process of purging the second source material, a process of supplying at least one hydrogen halide as a second reaction material and the organic material constituting the cleaning material into the process chamber, and a process of purging the second reaction material.

According to another embodiment, the process of removing impurities while depositing the compound of ABX₃ with the ALD process may include a process of supplying at least one compound selected from the amine-based compound and the amidine-based compound as a first source material into a process chamber, a process of purging the first source material, a process of supplying at least one hydrogen halide as a first reaction material into the process chamber, a process of purging the first reaction material, a process of supplying the organic metal compounds containing a divalent positive ion as a second source material and at least one hydrogen halide as a second reaction material into the process chamber, a process of purging the second source material and the second reaction material, a process of supplying the organic material constituting the cleaning material as a third reaction material into the process chamber, and a process of purging the third reaction material.

The process of supplying the organic material constituting the cleaning material may be performed after the process of supplying at least one compound selected from the amine-based compound and the amidine-based compound, the process of supplying the organic metal compounds containing a divalent positive ion, and the process of supplying at least one hydrogen halide.

Alternatively, the process of supplying the organic material constituting the cleaning material may be performed before at least one process among the process of supplying at least one compound selected from the amine-based compound and the amidine-based compound, the process of supplying the organic metal compounds containing a divalent positive ion, and the process of supplying at least one hydrogen halide.

Alternatively, the process of supplying the organic material constituting the cleaning material may be performed simultaneously with at least one process among the process of supplying at least one compound selected from the amine-based compound and the amidine-based compound, the process of supplying the organic metal compounds containing a divalent positive ion, and the process of supplying at least one hydrogen halide.

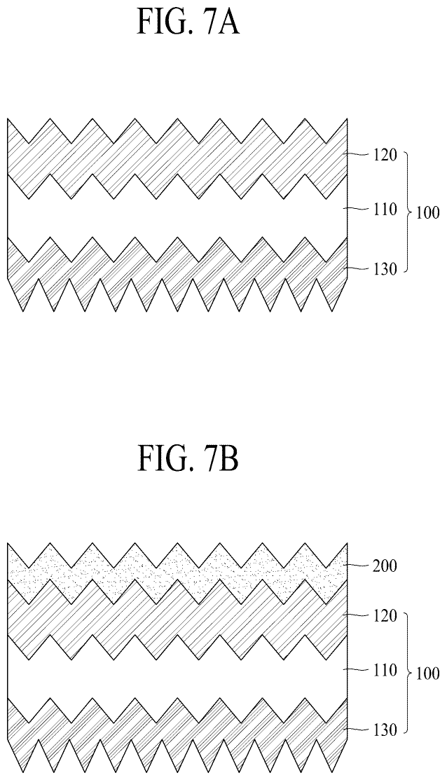

FIG. 5A is a thin film sample of a perovskite compound immediately after the deposition process according to an embodiment of this inventive concept, FIG. 5B is a thin film sample of a perovskite compound exposed to the atmosphere after the deposition process according to an embodiment of this inventive concept, and FIG. 5C is a thin film sample after adding a cleaning material to a thin film sample of a perovskite compound exposed to the atmosphere after the deposition process in accordance with an embodiment of this inventive concept.

As shown in FIG. 5A, the thin film sample of the perovskite compound right after the deposition process has a normal color of brown, but as shown in FIG. 5B, when the thin film sample of the perovskite compound is exposed to the atmosphere, it can be seen that the color changes from brown, which is a normal color, to white, which is an abnormal color, due to a phase change in the crystal structure.

In addition, as shown in FIG. 5C, when C₃H₈O of a cleaning material is added to a thin film sample of a perovskite compound that has changed to an abnormal color of white due to exposure to the atmosphere using the solution process, it changes from an abnormal color of white to a normal color of brown due to a phase change in the crystal structure.

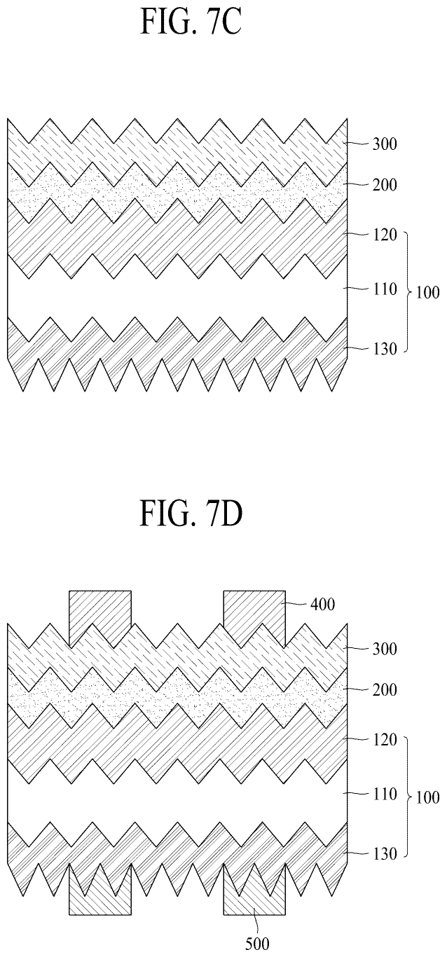

FIG. 6A is an XRD analysis result of a thin film sample of a perovskite compound exposed to the atmosphere after a deposition process according to an embodiment of this inventive concept, and FIG. 6B is an XRD analysis result of a thin film sample after adding a cleaning material to a thin film sample of a perovskite compound exposed to the atmosphere after a deposition process according to an embodiment of this inventive concept. FIG. 6A is an XRD analysis result of a thin film sample of FIG. 5B, and FIG. 6B is an XRD analysis result of a thin film sample of FIG. 5C.

As shown in FIG. 6A, the crystal structure when the thin film sample of the perovskite compound was exposed to the atmosphere was identified as a non-stoichiometric structure, but as shown in FIG. 6B, when C₃H₈O of the cleaning material was added to the thin film sample of the perovskite compound exposed to the atmosphere using the solution process, the crystal structure was again confirmed as a stoichiometric structure.

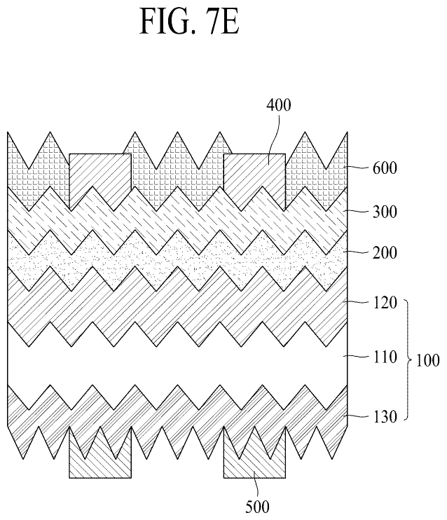

FIGS. 7A to 7E are process cross-sectional views illustrating a method of manufacturing a solar cell according to an embodiment of the present inventive concept.

First, as seen in FIG. 7A, a crystalline solar cell 100 is manufactured.

The crystalline solar cell 100 is manufactured through a process of etching one surface and the other surface of a semiconductor substrate 110 such as a wafer to form a concave-convex structure, doping a certain dopant on the one surface of the semiconductor substrate 110 to form a first semiconductor layer 120, and doping a certain dopant on the other surface of the semiconductor substrate 110 to form a second semiconductor layer 130.

As one surface and the other surface of the semiconductor substrate 110 are formed in the concave-convex structure, the first semiconductor layer 120 and the second semiconductor layer 130 are formed in a shape corresponding to the concave-convex structure.

On the other hand, the drawing shows that both one surface and the other surface of the semiconductor substrate 110 are formed in the concave-convex structure, but it is not necessarily limited to it. One surface of the semiconductor substrate 110 may be formed in the concave-convex structure and the other surface may be formed in a flat structure. Or, the other surface of the semiconductor substrate 110 may be formed in the concave-convex structure and one surface may be formed in a flat structure. In some cases, one surface and the other surface of the semiconductor substrate 110 may be formed in a flat structure.

The semiconductor substrate 110 may be formed of the P-type or N-type wafer, the first semiconductor layer 120 may be doped with a dopant having a polarity different from that of the semiconductor substrate 110, and the second semiconductor layer 130 may be doped with a dopant having the same polarity as that of the semiconductor substrate 110. For example, the semiconductor substrate 110 may be made of a P-type wafer, the first semiconductor layer 120 may be doped with an N-type dopant, and the second semiconductor layer 130 may be doped with a P-type dopant to form a P+ layer.

Subsequently, as seen in FIG. 7B, a buffer layer 200 is formed on the crystalline solar cell 100.

The buffer layer 200 is formed on the first semiconductor layer 120. As the first semiconductor layer 120 is formed in a concave-convex structure, the buffer layer 200 is formed in a shape corresponding to the concave-convex structure.

The buffer layer 200 is provided between the crystalline solar cell 100 and a below-described perovskite solar cell 300, and thus, a solar cell according to an embodiment of the present inventive concept has a structure of a tandem solar cell on the basis of a tunnel junction.

It is preferable that the buffer layer 200 includes a material for enabling light having a long wavelength, passing through the perovskite solar cell 300, to be incident on the crystalline solar cell 100 without being lost. For example, the buffer layer 200 may be formed of a transparent conductive oxide, a carbonaceous conductive material, a metallic material, or a conductive polymer, and in some cases, an n-type or p-type dopant may be doped with the material.

Subsequently, as seen in FIG. 7C, the perovskite solar cell 300 is formed on the buffer layer 200.

As the buffer layer 200 is formed in the concave-convex structure, the perovskite solar cell 300 may also be formed in the concave-convex structure.

The perovskite solar cell 300 may include a first conductive charge transporting layer disposed on the buffer layer 200, a light absorption layer disposed on the first conductive charge transporting layer, and a second conductive charge transporting layer disposed on the light absorption layer.

The first conductive charge transfer layer may be formed of an electron transfer layer and the second conductive charge transfer layer may be formed of a hole transfer layer. Or, the first conductive charge transfer layer may be formed of a hole transfer layer and the second conductive charge transfer layer may be formed of an electron transfer layer.

The electron transfer layer may include a compound including an N-type organic material, such as bathocuproine (BCP), C60, or phenyl-C61-butyric acid methyl ester (PCBM), or various N-type metal oxides such as ZnO, c-TiO₂/mp-TiO₂, SnO₂, or indium zinc oxide (IZO) known to those skilled in the art, or a N-type compound including various organic or inorganic materials known to those skilled in the art.

The hole transfer layer may include various P-type organic materials such as Spiro-MeO-TAD, Spiro-TTB, polyaniline, polyphenol, poly(3,4-ethylenedioxythiophene)-poly(styrenesulfonate) (PEDOT-PSS), poly[bis(4-phenyl)(2,4,6-trimethylphenyl)amine] (PTAA), and poly(3-hexylthiophene-2,5-diyl) (P3HT) known to those skilled in the art, or various P-type metal oxides such as Ni oxide, Mo oxide, V oxide, W oxide, or Cu oxide known to those skilled in the art, or a P-type compound including various organic or inorganic materials known to those skilled in the art.

The light-absorbing layer is made up of the thin film of the aforementioned perovskite compound, and therefore, a repeated description of the light-absorbing layer will be omitted.

Subsequently, as seen in FIG. 7D, a first electrode 400 is formed on a top surface of the perovskite solar cell 300, and a second electrode 500 is formed on a bottom surface of the crystalline solar cell 100.

Since the first electrode 400 is formed on an incident surface where sunlight is incident, the first electrode 400 is patterned in a predetermined shape. The second electrode 500 may also be configured to allow reflected light of sunlight to enter the solar cell by forming a pattern in a predetermined shape, but is not limited thereto.

Subsequently, as seen in FIG. 7E, a passivation layer 600 is formed on the first electrode 400. At this time, the first electrode 400 may be exposed by etching a portion of the passivation layer 600.

As the perovskite solar cell 300 is formed in the concave-convex structure, the passivation layer 600 may be formed in a concave-convex structure. The passivation layer 600 may be formed of various materials such as SiO, SiON, SiN, Al₂O₃, or MgF.

In particular, the passivation layer 600 may be made of polydimethylsiloxane, and when the polydimethylsiloxane is formed on the perovskite solar cell 300, a micro-pyramidal concave-convex structure may be obtained.

Hereinabove, the embodiments of the present inventive concept have been described in more detail with reference to the accompanying drawings, but the present inventive concept is not limited to the embodiments and may be variously modified within a range which does not depart from the technical spirit of the present inventive concept. Therefore, it should be understood that the embodiments described above are exemplary from every aspect and are not restrictive. It should be construed that the scope of the present inventive concept is defined by the below-described claims instead of the detailed description, and the meanings and scope of the claims and all variations or modified forms inferred from their equivalent concepts are included in the scope of the present inventive concept.

1. A method of forming a thin film of a perovskite compound comprising:
a process of depositing a perovskite compound by reacting at least one compound selected from amine-based compounds and amidine-based compounds, organic metal compounds containing a divalent positive ion, and at least one hydrogen halide; and
a process of removing impurities in the deposited perovskite compound.

2. The method of forming a thin film of a perovskite compound of claim 1, wherein the impurities are contained in a dangling bond state in a crystal structure of the perovskite compound.

3. The method of forming a thin film of a perovskite compound of claim 2, wherein the impurities include the at least one compound selected from the amine-based compounds and the amidine-based compounds that do not react with the organic metal compounds containing a divalent positive ion and the at least one hydrogen halide, and exist in the dangling bond state.

4. The method of forming a thin film of a perovskite compound of claim 2, wherein the impurities include the at least one hydrogen halide that does not react with the at least one compound selected from the amine-based compounds and the amidine-based compounds and the organic metal compounds containing a divalent positive ion, and exist in the dangling bond state.

5. The method of forming a thin film of a perovskite compound of claim 1, wherein the process of removing the impurities includes a process of reacting the impurities with an organic material by supplying the organic material to the perovskite compound.

6. The method of forming a thin film of a perovskite compound of claim 5, wherein the organic material is formed of a material capable of reacting with at least one of an amine-based compound, an amidine-based compound and hydrogen halide.

7. The method of forming a thin film of a perovskite compound of claim 6, wherein the organic material comprises carbon (C), hydrogen (H), and oxygen (O).

8. The method of forming a thin film of a perovskite compound of claim 7, wherein the organic material comprises C₃H₈O.

9. The method of forming a thin film of a perovskite compound of claim 1, wherein the impurities include a methyl amine in a dangling bond state, and the process of removing the impurities includes adding C₃H₈O to the perovskite compound to react the methyl amine in the dangling bond state with the C₃H₈O for producing CH₃NHOH and C₃H₈.

10. The method of forming a thin film of a perovskite compound of claim 1, wherein the impurities include a hydrogen iodide in a dangling bond state, and the process of removing the impurities includes adding C₃H₈O to the perovskite compound to react the hydrogen iodide in the dangling bond state with the C₃H₈O for producing C₂H₅I and CH₃OH.

11. The method of forming a thin film of a perovskite compound of claim 1, wherein the process of removing the impurities includes a process of reacting an organic material with the impurities after the process of depositing the perovskite compound, and
wherein the process of reacting the organic material with the impurities includes adding the organic material to the perovskite compound in a solution state.

12. The method of forming a thin film of a perovskite compound of claim 1, wherein the process of removing the impurities includes a process of reacting an organic material with the impurities after the process of depositing the perovskite compound, and
wherein the process of reacting the organic material with the impurities includes supplying the organic material into a chamber through a vaporizer or a bubbler.

13. The method of forming a thin film of a perovskite compound of claim 1, wherein the process of depositing the perovskite compound and the process of removing the impurities are simultaneously performed in a chamber.

14. The method of forming a thin film of a perovskite compound of claim 13, wherein the process of depositing the perovskite compound and the process of removing the impurities comprise:
a process of supplying a first source material including the at least one compound selected from the amine-based compound and the amidine-based compound;
a process of supplying a second source material including the organic metal compounds containing a divalent positive ion;
a process of supplying a first reaction material including the at least one hydrogen halide; and
a process of supplying a second reaction material including the organic material reacting with the impurities.

15. The method of forming a thin film of a perovskite compound of claim 14, wherein the process of supplying the second reaction material is performed after the process of supplying the first source material, the process of supplying the second source material, and the process of supplying the first reaction material.

16. The method of forming a thin film of a perovskite compound of claim 14, wherein the process of supplying the second reaction material is performed before at least one process among the process of supplying the first source material, the process of supplying the second source material, and the process of supplying the first reaction material.

17. The method of forming a thin film of a perovskite compound of claim 14, wherein the process of supplying the second reaction material is simultaneously performed with at least one process among the process of supplying the first source material, the process of supplying the second source material, and the process of supplying the first reaction material.

18. A method of manufacturing a solar cell comprising:
a process of forming a crystalline solar cell;
a process of forming a buffer layer on the crystalline solar cell;
a process of forming a perovskite solar cell on the buffer layer; and
a process of forming a first electrode on the perovskite solar cell and a second electrode on the crystalline solar cell,
wherein the process of forming the perovskite solar cell comprises a process of forming a thin film of a perovskite compound, and
wherein the process of forming the thin film of the perovskite compound comprises:
a process of depositing a perovskite compound by reacting at least one compound selected from amine-based compounds and amidine-based compounds, organic metal compounds containing a divalent positive ion, and at least one hydrogen halide; and
a process of removing impurities in the deposited perovskite compound.
